(19) United States
(12) Patent Application Publication
(10) Pub. No.: US 2012/0049386 A1
(43) Pub. Date: Mar. 1, 2012

(54) SEMICONDUCTOR PACKAGE

(75) Inventors: Hyung-Geun OH, Asan-si (KR); Chan-Suk LEE, Cheonan-si (KR); Sang-Hyeop LEE, Cheonan-si (KR)

(73) Assignee: Samsung Electronics Co., Ltd., Suwon-si (KR)

(21) Appl. No.: 13/185,732

(22) Filed: Jul. 19, 2011

(30) Foreign Application Priority Data
Aug. 25, 2010 (KR) 10-2010-0082242

(51) Int. Cl. H01L 23/48

(52) U.S. Cl. 257/777; 257/782; 257/E23.01

(57) ABSTRACT

A semiconductor package includes a package substrate, a semiconductor chip, an insulating layer pattern, conductive connecting members and a contact-preventing member. The semiconductor chip is arranged on an upper surface of the package substrate. The semiconductor chip has bonding pads. The insulating layer pattern is formed on the semiconductor chip to expose the bonding pads. The conductive connecting members electrically connect the bonding pads with the package substrate. The contact-preventing member covers an edge portion of the semiconductor chip to prevent a contact between the conductive connecting members and the semiconductor chip. Thus, the conductive connecting members do not make contact with the semiconductor chip.

### CROSS-REFERENCE TO RELATED APPLICATIONS

This application claims priority under 35 USC §119 to Korean Patent Application No. 10-2010-0082242, filed on Aug. 25, 2010 in the Korean Intellectual Property Office (KIPO), the disclosure of which is herein incorporated by reference in its entirety.

### BACKGROUND OF THE INVENTION

1. Field of the Invention

Exemplary embodiments relate to a semiconductor package and a method of manufacturing the same. More particularly, exemplary embodiments relate to a semiconductor package including conductive wires, and a method of manufacturing the semiconductor package.

2. Description of the Related Art

Generally, a plurality of semiconductor fabrication processes may be performed on a semiconductor substrate to form a plurality of semiconductor chips. In order to mount the semiconductor chips on a printed circuit board (PCB), a packaging process may be performed on the semiconductor chips to form semiconductor packages.

A semiconductor package may include a package substrate, a semiconductor chip, conductive wires, a molding member and external terminals. The semiconductor chip may be mounted on an upper surface of the package substrate. The conductive wires may electrically connect bonding pads of the semiconductor chip with the package substrate. The molding member may be formed on the upper surface of the package substrate to cover the semiconductor chip and the conductive wires. The external terminals may be mounted on a lower surface of the package substrate.

The conductive wires may electrically connect the bonding pads with the package substrate over an edge portion of the semiconductor chip. The conductive wires may make contact with the edge portion of the semiconductor chip, so that an electrical short between the conductive wires and the semiconductor chip may be frequently generated. Particularly, in a multi-chip package including a plurality of the semiconductor chips sequentially stacked, a distance from an upper semiconductor chip to a package substrate may be long. Thus, conductive wires may also have a long length. The long conductive wires may make contact with the semiconductor chip to generate an electrical short.

In order to prevent the electrical short, an additional member for preventing the contact between the semiconductor chip and the conductive wire may be formed at the edge portion of the semiconductor chip. However, because the additional member may be formed by an additional process, semiconductor fabrication processes may be complicated.

### SUMMARY OF THE INVENTION

Exemplary embodiments provide a semiconductor package capable of preventing a contact between a semiconductor chip and a conductive wire without an additional process.

Exemplary embodiments also provide a method of manufacturing the above-mentioned semiconductor package.

Additional aspects and advantages of the present general inventive concept will be set forth in part in the description which follows and, in part, will be obvious from the description, or may be learned by practice of the general inventive concept.

According to exemplary embodiments, there is provided a semiconductor package. The semiconductor package may include a package substrate, a semiconductor chip, an insulating layer pattern, conductive connecting members and a contact-preventing member. The semiconductor chip may be arranged on an upper surface of the package substrate. The semiconductor chip may have bonding pads. The insulating layer pattern may be formed on the semiconductor chip to expose the bonding pads. The conductive connecting members may electrically connect the bonding pads with the package substrate. The contact-preventing member may be configured to cover an edge portion of the semiconductor chip to prevent a contact between the conductive connecting members and the semiconductor chip.

The contact-preventing member may include a body portion formed on the edge portion of the semiconductor chip, and a contact-preventing portion extending from the body portion and protruding from the edge portion of the semiconductor chip to prevent the contact between the conductive connecting members and the semiconductor chip. The contact-preventing portion may have a thickness less than that of the body portion. The contact-preventing member may further include a fillet portion connected between the body portion and the contact-preventing portion at the edge portion of the semiconductor chip.

The contact-preventing member may be a part of the insulating layer pattern. The contact-preventing member may include a material substantially the same as that of the insulating layer pattern. The material may include oxide, polyimide, photosensitive polyimide, etc.

The conductive connecting members may include conductive wires.

The semiconductor package may further include a molding member formed on the upper surface of the package substrate to cover the semiconductor chip and the conductive connecting members.

The semiconductor package may further include external terminals mounted on a lower surface of the package substrate.

According to exemplary embodiments, there is provided a method of manufacturing a semiconductor package. In the method of manufacturing the semiconductor package, an insulating layer pattern may be formed on an upper surface of a wafer including a plurality of semiconductor chips to expose bonding pads of the semiconductor chips. The wafer may be cut from a lower surface of the wafer toward the insulating layer pattern to convert a portion of the insulating layer pattern on an edge portion of each of the semiconductor chips into a contact-preventing member configured to cover the edge portion of each of the semiconductor chips. The semiconductor chips may be mounted on a package substrate. The bonding pads of the semiconductor chips may be electrically connected with the package substrate using conductive connecting members over the contact-preventing member.

Converting the portion of the insulating layer pattern into the contact-preventing member may include cutting the wafer to form an opening blocked by a portion of the insulating layer pattern between the semiconductor chips, and cutting the portion of the insulating layer pattern in the opening to form the contact-preventing member. Converting the portion of the insulating layer pattern into the contact-preventing member may further include partially removing the portion of the insulating layer pattern in the opening. Partially removing the portion of the insulating layer pattern in the opening may include forming a fillet portion at the contact-preventing layer member.

The method may further include forming a molding member on the upper surface of the package substrate to cover the semiconductor chip and the conductive connecting members.

The method may further include mounting external terminals on a lower surface of the package substrate.

According to exemplary embodiments, the contact-preventing member may cover the edge portion of the semiconductor chip, so that the conductive connecting members may not make contact with the semiconductor chip. Particularly, the contact-preventing member may be formed by cutting the wafer. Thus, it may not be required to perform an additional process for forming the contact-preventing member. As a result, semiconductor fabrication processes may not become complicated.

The foregoing and other aspects and utilities of the present general inventive concept may be achieved by providing a semiconductor package including a package substrate, a semiconductor chip mounted on the package substrate, the semiconductor chip having a bonding pad, a conductive connecting member electrically connected between the bonding pad and the package substrate, and a contact-preventing member formed on an upper edge surface of the semiconductor chip between the bonding pad and a corner portion of the semiconductor chip to maintain a distance between the conductive connecting member and the semiconductor chip.

The semiconductor package may further include an insulating layer pattern formed on the semiconductor chip and formed with the contact-preventing member in a monolithic single body.

The insulating layer pattern may include an opening to surround the bonding pad.

The semiconductor package may further include an opening formed between the insulating layer pattern and the contact-preventing member to expose the bonding pad.

The insulating layer pattern may include a center portion and a portion extended from the center portion and connected to the contact-preventing member, and the portion of the insulating layer patter may be disposed adjacent to the bonding pad.

The insulating layer pattern may have a constant thickness, and the contact-preventing member may have a variable thickness.

The insulating layer pattern and the contact-preventing member may be disposed in a same direction, and the contact-preventing member may include a contact-preventing portion extended from a corner portion of the semiconductor as an overhanging portion to overhang the package substrate such that the conductive connecting member is prevented from contacting a side of the semiconductor chip.

The contact-preventing member may include a body portion formed adjacent to the bonding pad on the upper edge surface of the semiconductor chip, and a contact-preventing portion extending from the body portion to protrude from the upper edge surface of the semiconductor chip to prevent the contact between the conductive connecting member and the semiconductor chip. The conductive connecting member may contact the contact-preventing portion of the contact-preventing member.

The semiconductor package may include a molding member formed to cover the package substrate, the semiconductor chip, the conductive connecting member, and the contact-preventing member. The molding member may be filled in between the contact-preventing member and the conductive connecting member.

The bonding pad may include a plurality of sub-bonding pads disposed along a line of the semiconductor chip, the conductive connecting member may include a plurality of sub-conductive connecting member to correspond to the corresponding sub-bonding pads, and the contact-preventing member may be formed in a single body along the line of the semiconductor to correspond to the sub-bonding pads.

The semiconductor package may include a second package substrate disposed on the insulating layer pattern, a second semiconductor chip mounted on the second package substrate, the second semiconductor chip having a second bonding pad, a second conductive connecting member electrically connected between the second bonding pad and the package substrate, and a second contact-preventing member formed on an upper edge surface of the second semiconductor chip between the second bonding pad and a second corner portion of the second semiconductor chip to maintain a second distance between the second conductive connecting member and the second semiconductor chip.

The contact-preventing member may have a first dimension and the second contact-preventing member may have a second dimension.

The foregoing and other aspects and utilities of the present general inventive concept may also be achieved by providing an electronic apparatus including a semiconductor package including a package substrate, a semiconductor chip mounted on the package substrate, the semiconductor chip having a bonding pad, a conductive connecting member electrically connected between the bonding pad and the package substrate, a contact-preventing member formed on an upper edge surface of the semiconductor chip between the bonding pad and a corner portion of the semiconductor chip to maintain a distance between the conductive connecting member and the semiconductor chip, and a molding member. The electronic apparatus may further include a control unit connected to the semiconductor package to control data of the semiconductor chip.

The foregoing and other aspects and utilities of the present general inventive concept may also be achieved by providing an electronic apparatus including a semiconductor package including a package substrate, a semiconductor chip mounted on the package substrate, the semiconductor chip having a bonding pad, a conductive connecting member electrically connected between the bonding pad and the package substrate, a contact-preventing member formed on an upper edge surface of the semiconductor chip between the bonding pad and a corner portion of the semiconductor chip to maintain a distance between the conductive connecting member and the semiconductor chip, and a molding member. The electronic apparatus may further include a function unit to perform a function thereof, an interface to communicate with an external device, and a processor to control the semiconductor package to process data stored in the semiconductor chip, to control the function unit using the processed data, and to control the interface unit to receive the data and transmit the processed data from and to the external device.

### BRIEF DESCRIPTION OF THE DRAWINGS

Exemplary embodiments will be more clearly understood from the following detailed description taken in conjunction with the accompanying drawings. FIGS. 1 to 10 represent non-limiting, exemplary embodiments as described herein.

These and/or other aspects and advantages of the present general inventive concept will become apparent and more readily appreciated from the following description of the embodiments, taken in conjunction with the accompanying drawings of which:

FIG. 1 is a cross-sectional view illustrating a semiconductor package in accordance with exemplary embodiments;

FIG. 2A is an enlarged cross-sectional view of a portion “II” in FIG. 1;

FIGS. 2B through 2H are views illustrating a portion of “II” of FIG. 1 according to embodiments of the present general inventive concept;

FIGS. 3 to 9 are cross-sectional views illustrating a method of manufacturing the semiconductor package in FIG. 1;

FIG. 10 is a cross-sectional view illustrating a multi-chip package including the semiconductor package in FIG. 1;

FIG. 11 is a view illustrating a portion of the multi-chip package of FIG. 10; and

FIGS. 12A and 12B are view illustrating an electronic apparatus and a semiconductor package according to an embodiment of the present general inventive concept.

### DETAILED DESCRIPTION OF THE PREFERRED EMBODIMENTS

Reference will now be made in detail to the embodiments of the present general inventive concept, example of which are illustrated in the accompanying drawings, wherein like reference numerals refer to the like elements throughout. The embodiments are described below in order to explain the present general inventive concept while referring to the figures. The present inventive concept may, however, be embodied in many different forms and should not be construed as limited to the exemplary embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For exemplary, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for exemplary, of manufacturing techniques and/or tolerances, are to be expected. Thus, exemplary embodiments should not be construed as limited to the particular shapes of regions illustrated herein but are to include deviations in shapes that result, for exemplary, from manufacturing. For exemplary, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

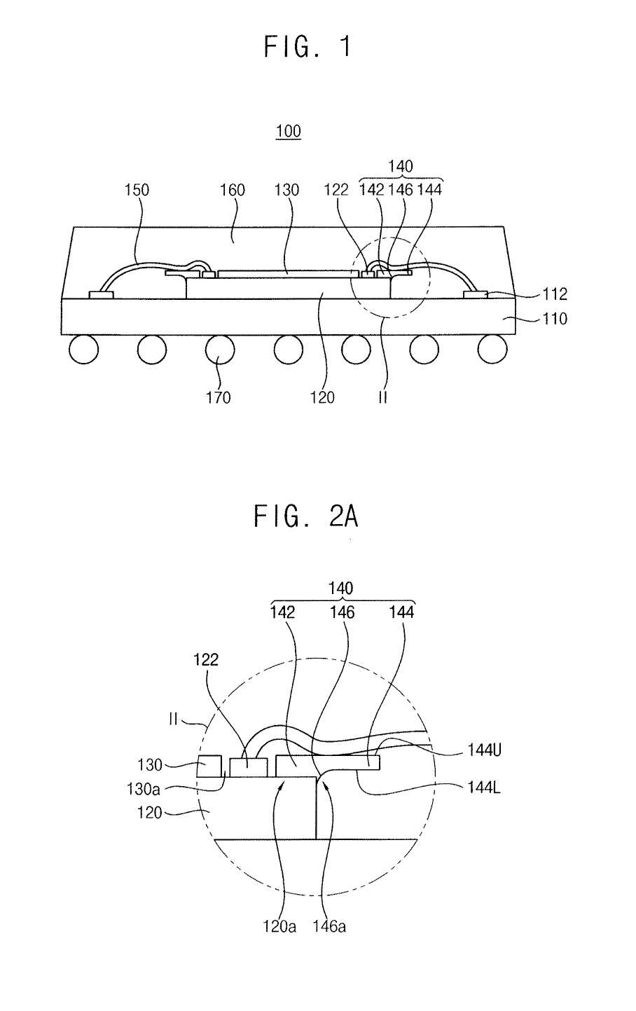

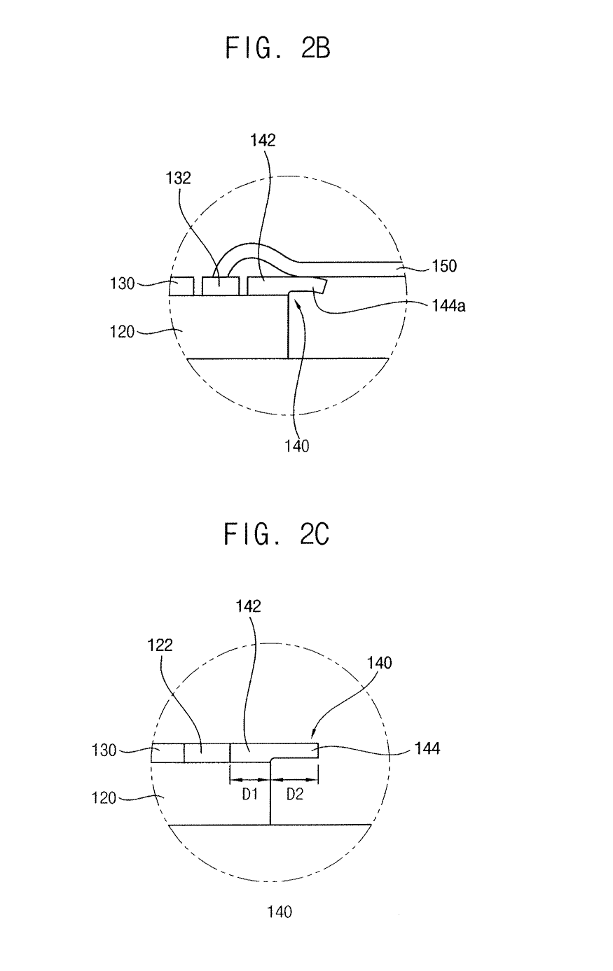

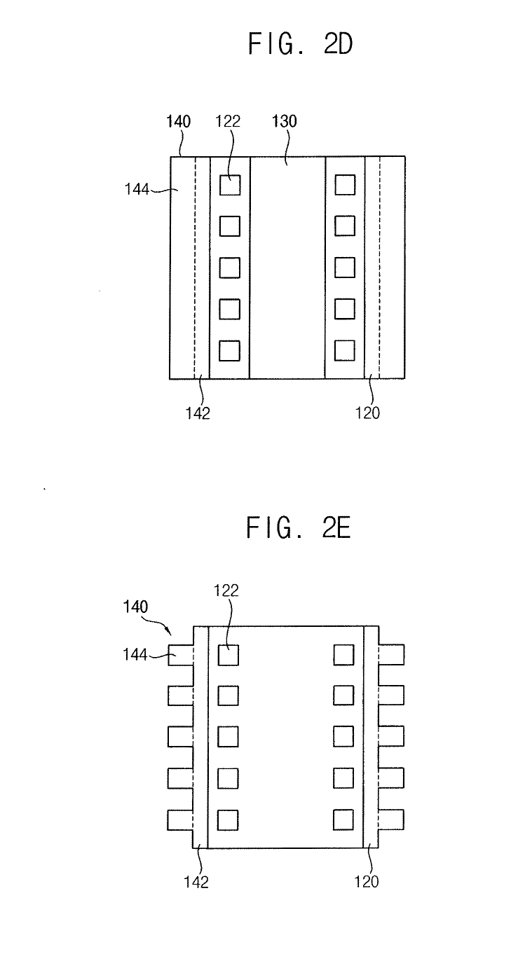

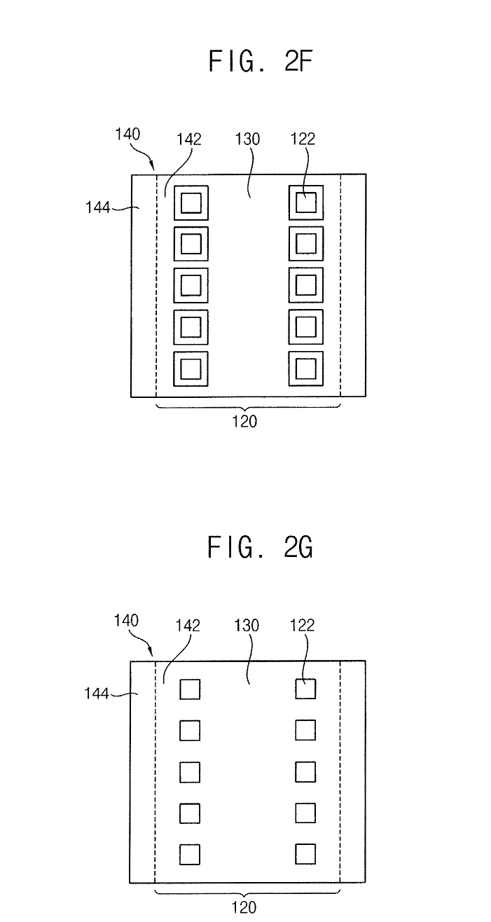

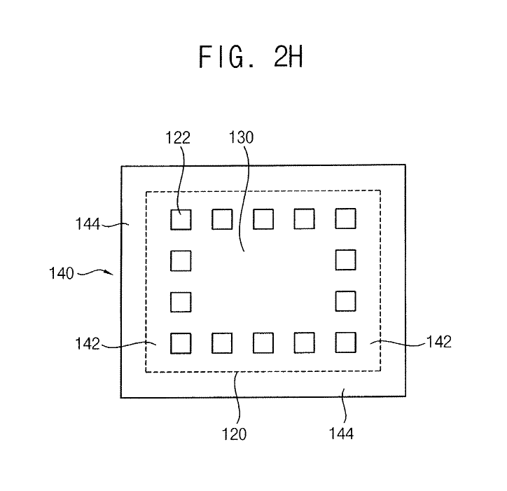

FIG. 1 is a cross-sectional view illustrating a semiconductor package 100 according to an exemplary embodiment of the present general inventive concept, and FIG. 2A is an enlarged cross-sectional view of a portion “II” in FIG. 1.

Referring to FIGS. 1 and 2, the semiconductor package 100 of this exemplary embodiment may include a package substrate 110, a semiconductor chip 120, an insulating layer pattern 130, a contact-preventing member 140, conductive connecting members 150, a molding member 160 and external terminals 170.

The package substrate 110 may include an insulating substrate, a circuit pattern (not shown) formed on or in the insulating substrate, upper and lower pads 112 formed on an upper surface and a lower surface of the insulating substrate. The pads 112 may be electrically connected with the circuit pattern. The upper pads 112 may be arranged on an edge portion of the upper surface of the package substrate 110.

The semiconductor chip 120 may be arranged on an upper surface of the package substrate 110. The semiconductor chip 120 may have bonding pads 122. The bonding pads 122 may be arranged on an upper edge portion (or upper edge surface) 120a of the semiconductor chip 120.

The insulating layer pattern 130 may be formed on an upper central surface of the semiconductor chip 120. The insulating layer pattern 130 may have openings 130a configured to expose the bonding pads 122. The insulating layer pattern 130 may include oxide, polyimide, photosensitive polyimide, etc.

The contact-preventing member 140 may be arranged on the upper edge surface 120a of the semiconductor chip 120. The contact-preventing member 140 may prevent an electrical contact between the conductive connecting members 150 and the upper edge surface 120a of the semiconductor chip 120.

The contact-preventing member 140 may be configured to cover the upper edge surface 120a of the semiconductor chip 120. The contact-preventing member 140 may include a body portion 142, a contact-preventing portion 144 and a fillet portion 146. The body portion 142 may be arranged on the upper edge surface 120a of the semiconductor chip 120. The contact-preventing portion 144 may extend from the body portion 142 in a direction outside of the semiconductor chip 120. The contact-preventing portion 144 may extend from the body portion 142. It is possible that the contact-preventing portion 144 may horizontally extend from the body portion 142 toward the pads 112 of the package substrate 110. It is also possible that the contact-preventing portion 144 may protrude from the upper edge surface 120a of the semiconductor chip 120 to form an angle with a side of the semiconductor chip 120. It is also possible that the contact-preventing portion 144 may be disposed between the conductive connecting member 150 and at least one of the upper surface and the side surface of the semiconductor chip 120. It is also possible that the contact-preventing portion 144 may be disposed between the conductive connecting member 150 and a corner portion of the semiconductor chip 12.

The body portion 142 may have one end terminated (or disposed) at an end of the upper surface of the semiconductor chip 120. The contact-preventing portion 144 may extend from the one end of the body portion 142. Thus, the contact-preventing portion 144 may protrude from the one end of the upper surface of the semiconductor chip 120. That is, the contact-preventing portion 144 may be configured to fully cover the upper edge surface 120a of the semiconductor chip 120. The conductive connecting member 150 may be surmounted on the contact-preventing portion 144, so that the conductive connecting member 150 may not make contact with the upper edge surface of the semiconductor chip 120.

In some exemplary embodiments, the contact-preventing portion 144 may have a thickness less than that of the body portion 142. The contact-preventing portion 144 may have an upper surface 144U substantially coplanar with that of the body portion 142. However, the contact-preventing portion 144 may have a lower surface 144L higher than that of the body portion 142 with respect to the upper surface of the semiconductor chip 120. Therefore, the thickness of the contact-preventing portion 144 may be less than that of the body portion 142 by a distance between the lower surface 144L of the contact-preventing portion 144 and the lower surface of the body portion 142.

In an exemplary embodiment, because the body portion 142 may be positioned on the upper edge surface 120a of the semiconductor chip 120, the body portion 142 may be firmly supported by the semiconductor chip 120. However, because the contact-preventing portion 144 protrudes from an upper end of the semiconductor chip 120, the contact-preventing portion 144 may not be supported by the semiconductor chip 120. In order to reinforce strength of the contact-preventing portion 144, the fillet portion 146 may be formed at an intersected portion between lower surfaces of the body portion 142 and the contact-preventing portion 144. The fillet portion 146 may have a portion 146a, which may have a rounded shape, configured to reinforce connection strength between the body portion 142 and the contact-preventing portion 144. That is, when the intersected portion between the lower surfaces of the body portion 142 and the contact-preventing portion 144 may have a right angle, the contact-preventing portion 144 may be deflected due to a weight of the contact-preventing portion 144. However, the fillet portion 146 formed at the intersected portion between the lower surfaces of the body portion 142 and the contact-preventing portion 144 may reinforce the connection strength between the body portion 142 and the contact-preventing portion 144, so that the deflection of the contact-preventing portion 144 may be suppressed (or prevented).

The portion 146a of the fillet portion 146 may have one end covering one end of the upper surface of the semiconductor 120 and other end connected to the lower surface 144L of the contact-preventing portion 144. It is possible that the one end of the portion 146a of the fillet portion 146 may extend from a corner portion of the semiconductor 120. However, the present general inventive concept is not limited thereto. It is possible that the one end of the portion 146a of the fillet portion 146 may cover at least a portion of a side surface of the semiconductor 120 according to a process of manufacturing the semiconductor package 100. It is also possible that the one end of the portion 146a of the fillet portion 146 may extend from one end of the side surface of the semiconductor chip 120 toward the lower surface 144L of the contact-preventing portion 144 or toward a portion of the conductive connecting member 150.

In an exemplary embodiment, the contact-preventing member 140 may be a part of the insulating layer pattern 130. That is, the contact-preventing member 140 may be converted from a portion of the insulating layer pattern 130, which may be positioned on the upper edge surface 120a of the semiconductor chip 120, by cutting a wafer. Thus, the contact-preventing member 140 may include a material substantially the same as that of the insulating layer pattern 130. As a result, the contact-preventing member 140 may include oxide, polyimide, photosensitive polyimide, etc.

The conductive connecting members 150 may electrically connect the bonding pads 122 of the semiconductor chip 120 with the pads 112 of the package substrate 110 and may have a portion disposed over the contact-preventing member 140. When the conductive connecting member 150 may have a long loop, the conductive connecting member 150 may be surmounted on (or may be in contact with) the upper surface of the contact-preventing member 140. Therefore, the long conductive connecting member 150 may not make contact with the upper edge surface of the semiconductor chip 120. As a result, an electrical short between the conductive connecting member 150 and the semiconductor chip 120 may be prevented. In exemplary embodiments, the conductive connecting members 150 may include conductive wires such as gold wires, aluminum wires, etc.

The molding member 160 may be formed on the upper surface of the package substrate 110 to cover the semiconductor chip 120 and the conductive connecting members 150. The molding member 160 may protect the semiconductor chip 120 and the conductive connecting members 150 from external environments. In some exemplary embodiments, the molding member 160 may include an epoxy molding compound (EMC).

The external terminals 170 may be arranged on a lower surface of the package substrate 110. That is, the external terminals 170 may be mounted on the lower pads of the package substrate 110. In exemplary embodiments, the external terminals 170 may include solder balls.

Although FIG. 2A illustrates that the conductive contacting member 150 contacts the fillet portion 146 and/or the contact preventing portion 144, it is possible that the conductive contacting member 150 may contact the body portion and extend along the contact preventing portion 144. It is also possible that the conductive contacting member 150 may contact a distal end of the contact preventing portion 144.

Referring to FIG. 2B, a contact preventing portion 144a of the contact preventing member 140 may have a distal end which may not be at the same position as the other end of the contact-preventing portion 144a disposed close to the fillet portion 146 or the body portion 142 as illustrated in FIG. 2A, with respect to the upper surface of the semiconductor chip 120. It is possible that the contact preventing portion 144 of FIG. 2A may be deformed as the contact preventing portion 144a of FIG. 2B during a manufacturing process.

Referring to FIG. 2C, the body portion 142 may have a length D1 and the contact preventing portion 144 may have a length D2 which is different from the length D1. In this case, the length D2 may include lengths of the fillet portion 146 and the contact preventing portion 144. However, the present general inventive concept is not limited thereto. The lengths D1 and D2 may be same.

Referring to FIG. 2D, the contact preventing portion 144 may be a single body extended from the body portion 142 and/or the fillet portion 146 to correspond to a plurality of the bonding pads 122. Referring to FIG. 2E, the contact preventing portion 144 may have a plurality of sub-contact preventing portions formed from the body portion 142 and/or the fillet portion 146 to correspond to the respective bonding pads 122. The sub-contact preventing portions may be spaced-apart from each other by a distance. The distance may be shorter than a thickness of the conductive contacting member 150. However, the present inventive concept is not limited thereto. The distance may vary according to the manufacturing process.

Referring to FIG. 2F, the openings 130 are formed around the corresponding bonding pads 122 as illustrated in FIG. 2A. It is possible that one opening may be formed to surround at least two bonding pads 122. In this case, the number of the openings 130 may be less than the number of the bonding pads 122. Referring to FIG. 2G, an opening may not be formed between the bonding pad 122 and the contact preventing member 140 during a manufacturing process.

Referring to FIG. 2H, the contact preventing member 140 is formed to correspond to more than two portions of the semiconductor chip 120. In this embodiment, the bonding pads 122 are formed on four upper portions of the semiconductor chip 120, and four contact preventing members are formed to correspond to four sets of the bonding pads formed along the corresponding upper portions of the semiconductor chip 120.

FIGS. 3 to 9 are cross-sectional views illustrating a method of manufacturing the semiconductor package in FIG. 1.

Referring to FIG. 3, the insulating layer pattern 130 may be formed on an upper surface of a wafer W. In some exemplary embodiments, the semiconductor chips 120 may be formed in the wafer W. Each of the semiconductor chips 120 may have bonding pads 122. The insulating layer pattern 130 may have the openings configured to expose the bonding pads 122.

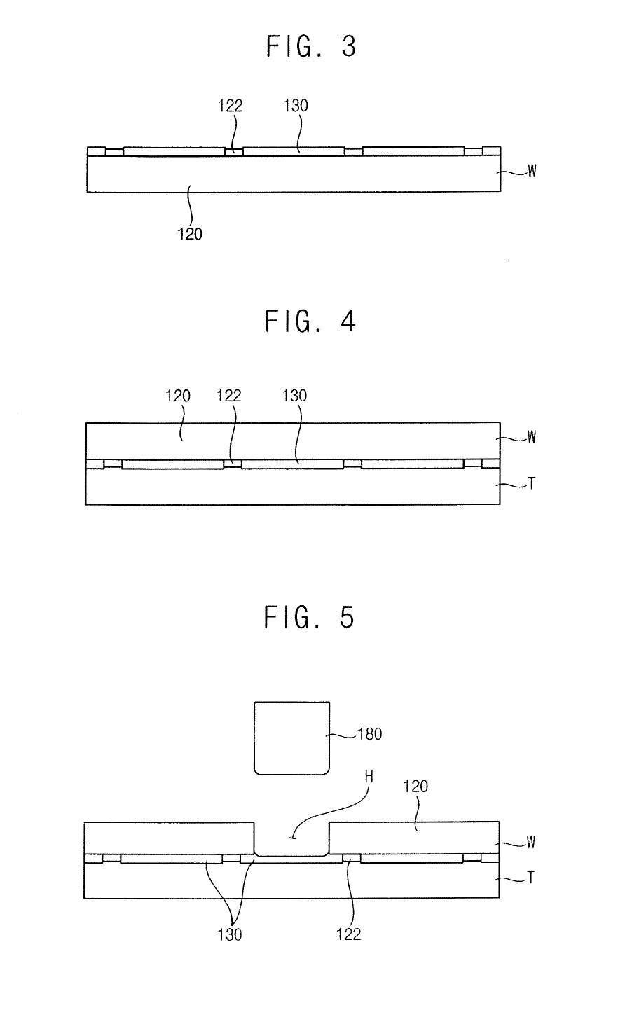

Referring to FIG. 4, the wafer W may be turned over. Thus, the insulating layer pattern 130 may be downwardly oriented, and a lower surface of the wafer W may be upwardly oriented. A supporting tape T may be attached on the insulating layer pattern 130.

Referring to FIG. 5, a first blade 180 may cut a scribe lane of the wafer W. In some exemplary embodiments, because the lower surface of the wafer W may be upwardly oriented, the first blade 180 may cut the wafer W from the lower surface of the wafer W toward the insulating layer pattern 130 to form an opening H.

In exemplary embodiments, the first blade 180 may partially cut the insulating layer pattern 130 and entirely cut the wafer W. The first blade 180 may cut the wafer W to separate bodies of the semiconductor chips 120 but partially cut the insulating layer pattern 130. That is, a lower end of the first blade 180 may press a portion of the insulating layer pattern 130 in the opening H. Thus, the portion of the insulating layer pattern 130 in the opening H may have a thickness slightly less than that of other portions of the insulating layer pattern 130 on the wafer W. Here, the relatively thick portion of the insulating layer pattern 130 may correspond to the body portion 142 of the contact-preventing member 140. The relatively thin portion of the insulating layer pattern 130 may correspond to the contact-preventing portion 144 of the contact-preventing member 140.

In some exemplary embodiments, both lower ends of the first blade 180 may have a rounded shape. Thus, after the lower ends of the first blade 180 may press the portion of the insulating layer pattern 130, the portion of the insulating layer pattern 130 may also have a rounded shape. The rounded portion of the insulating layer pattern 130 may correspond to the fillet portion 146 of the contact-preventing member 140. A shape of the fillet portion 146 may be determined according to a shape of the first blade 180.

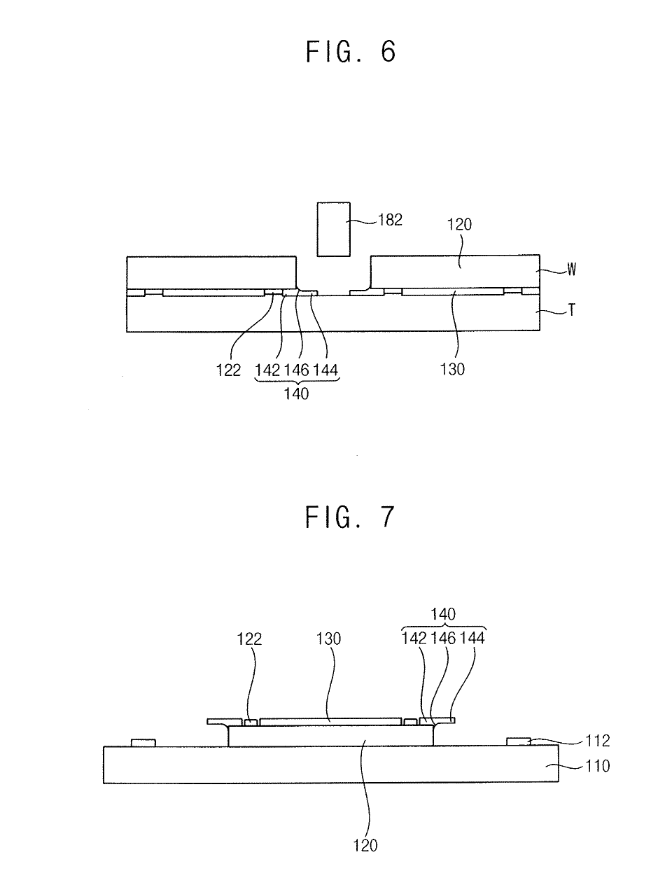

Referring to FIG. 6, a second blade 180 may cut the portion of the insulating layer pattern 130 in the opening H. Thus, the portion of the insulating layer pattern 130, which may be connected between the adjacent semiconductor chips 120, may be removed, so that the semiconductor chips 120 may be separated from each other by disconnection of the insulating layer pattern 130. Simultaneously, the contact-preventing member 140 configured to cover the upper edge surface of the semiconductor chip 120 may be formed. That is, the contact-preventing member 140 may be formed from the insulating layer pattern 130 by a cutting process of the wafer W, without an additional process. Therefore, it may not be required to perform the additional process for forming the contact-preventing member 140.

Referring to FIG. 7, the semiconductor chip 120 may be turned upside down. Thus, the insulating layer pattern 130 and the contact-preventing member 140 may be upwardly oriented. The semiconductor chip 120 may be arranged on the package substrate 110.

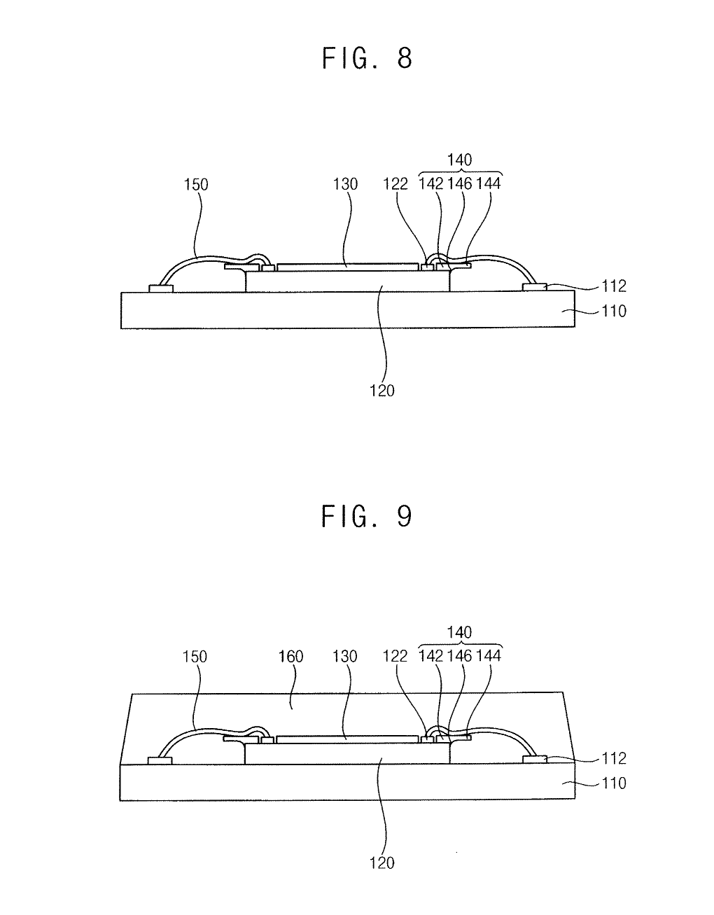

Referring to FIG. 8, the conductive connecting members 150 may electrically connect the bonding pads 122 of the semiconductor chip 120 with the pads 112 of the package substrate 110. The conductive connecting members 150 may be surmounted on the contact-preventing member 140, so that an electrical short between the conductive connecting members 150 and the semiconductor chip 120. The conductive connecting members 150 are prevented from contacting the semiconductor chip 120.

It is possible that the conductive connecting member 150 may have a portion disposed over the contact preventing member 140. In this case, the conductive connecting member 150 may not be in contact the contact preventing member 140 when being connected to the bonding pads 122 of the semiconductor chip 120 and the pads 112 of the package substrate 110. However, the conductive connecting member 150 may be in contact with the contact preventing member 140 during a manufacturing process.

Referring to FIG. 9, the molding member 160 may be formed on the upper surface of the package substrate 110 to cover the semiconductor chip 120 and the conductive connecting members 150.

The external terminals 170 may be mounted on the lower surface of the package substrate 110 to complete the semiconductor package 100 in FIG. 1.

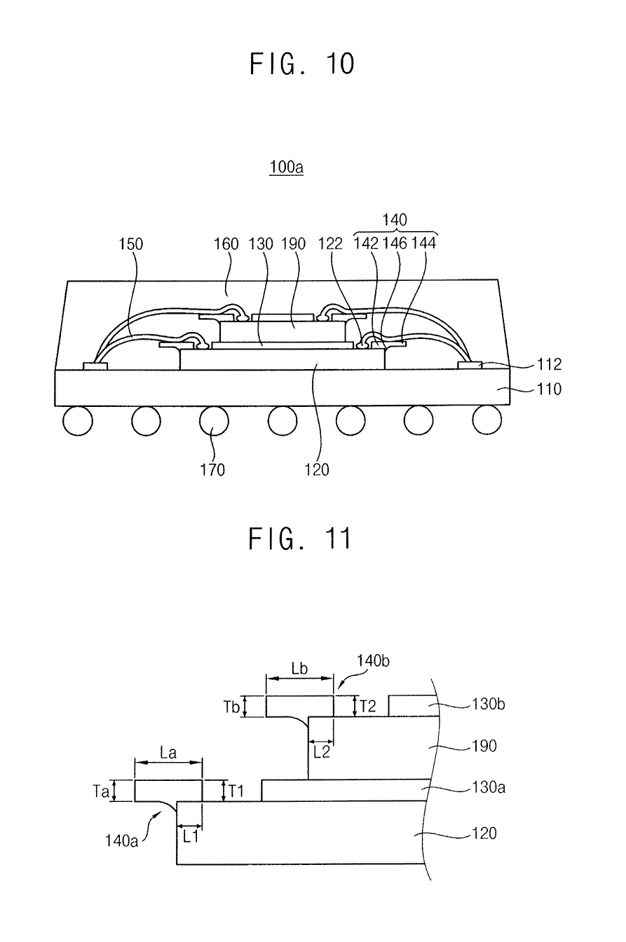

FIG. 10 is a cross-sectional view illustrating a multi-chip package including the semiconductor package in FIG. 1.

A multi-chip package 100a of this embodiment may include elements substantially the same as those of the semiconductor package 100 in FIG. 1 except for further including a second semiconductor chip 190. Thus, the same reference numerals may refer to the same elements, and any further illustrations with respect to the same element may be omitted herein for brevity.

Referring to FIG. 10, the second semiconductor chip 190 may be stacked on an upper surface of the semiconductor chip 120. The second semiconductor chip 190 may include bonding pad (not shown) electrically connected with the pads 112 of the package substrate 110 via the contact-preventing member 140 through conductive wires. The second semiconductor chip 190 may include elements substantially the same as that of the semiconductor chip 120 except for a size. That is, the contact-preventing member may be formed on an upper edge surface of the second semiconductor chip 190. Thus, any further illustrations with respect to the second semiconductor chip 190 may be omitted herein for brevity. The size of the second semiconductor chip 190 may be smaller than that of the semiconductor chip 120 to expose the bonding pads 122 of the semiconductor chip 120.

A distance between the bonding pad of the second semiconductor chip 190 and the pad 112 of the package substrate 110 may be long. Thus, the conductive wire may also have a long length, so that the long conductive wire may make contact with the upper edge surface of the second semiconductor chip 190. However, the long conductive wire may be surmounted on the contact-preventing member. As a result, the long conductive wire may not make contact with the upper edge surface of the second semiconductor chip 190.

A method of manufacturing a multi-chip package in accordance with this exemplary embodiment may include processes substantially the same as those illustrated with reference to FIGS. 3 to 9 except for further including a process for stacking the second semiconductor chip 190 on the semiconductor chip 120. Thus, any further illustrations with respect to the method may be omitted herein for brevity.

Referring to FIG. 11, a contact preventing member 140a is formed on the semiconductor chip 120, and a contact preventing member 140b is formed on the second semiconductor chip 190. An insulating layer pattern 130a is formed on the semiconductor chip 120, and a second insulating layer pattern 130b may be formed on the second semiconductor chip 190. The second semiconductor chip 190 may be mounted on the second insulating layer pattern 130a. The body portion 142 of the contact preventing member 140a may have a thickness T1 and the body portion 142 of the second preventing member 140b may have a thickness T2. The contact preventing portion 144 of the contact preventing member 140a may have a thickness Ta and the contact preventing portion 144 of the second preventing member 140b may have a thickness Tb. The body portion 142 of the contact preventing member 140a may have a length L1, and the body portion 142 of the second preventing member 140b may have a length L2. The contact preventing member 140a may have a length La, and the second contact preventing member 140b may have a length Lb. These dimensions may vary according to a design selection and a manufacturing process.

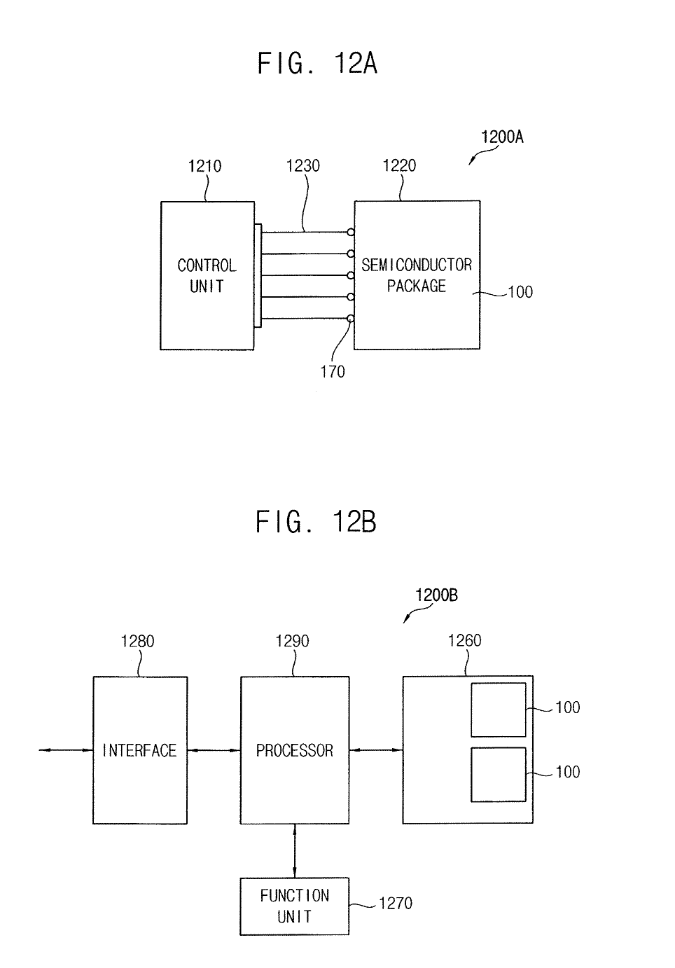

Referring to FIG. 12A, a semiconductor package 1200A may include a control unit 1210 and a semiconductor package 1220. The semiconductor packages illustrated in FIGS. 1 through 11 can be used as the semiconductor package 1220. The semiconductor package 1200A may be an electronic apparatus having the control unit 1210 to control the semiconductor package 1220 to process data to be stored in the semiconductor package 1220 or read the data and process the read data in the semiconductor package 1220. The semiconductor package 1220 may have external terminals 170 to be connected to a terminal unit of the control unit 1210 through conductive lines 1230. The semiconductor package 1200A may be a module or a computer system.

Referring to FIG. 12B, an electronic apparatus 1200B may include a semiconductor package 1260, a function unit 1270, an interface 1280, and a processor 1290. The semiconductor packages illustrated in FIGS. 1 through 12A may be used as the semiconductor package 1260. The function unit 1270 may be a unit to perform a process of the electronic apparatus 1200B, for example, a video image signal processing, an audio signal processing, a data processing, an image or sound forming processing, etc. Since the function unit and the processes are well known, detail descriptions thereof will be omitted. The interface 1280 may communicate with an external device according to a wired or wireless communication method and may be connected to the processor 1290. The processor 1290 may control functions and processes of the electronic apparatus 1200B. The semiconductor package 1260 may include a plurality of the semiconductor packages 100, for example. The electronic apparatus 1200B may be a computer system, a portable apparatus, etc.

According to some exemplary embodiments, the contact-preventing member may cover the edge portion of the semiconductor chip, so that the conductive connecting members may not make contact with the semiconductor chip. Particularly, the contact-preventing member may be formed by cutting the wafer. Thus, it may not be required to perform an additional process for forming the contact-preventing member. As a result, semiconductor fabrication processes may not become complicated.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

1. A semiconductor package comprising:
a package substrate;
a semiconductor chip mounted on the package substrate, the semiconductor chip having a bonding pad;
an insulating layer pattern formed on the semiconductor chip, the insulating layer pattern having an opening configured to expose the bonding pads;
a conductive connecting member electrically connected between the bonding pad and the package substrate; and
a contact-preventing member configured to cover an upper edge surface of the semiconductor chip to prevent a contact between the conductive connecting member and the semiconductor chip.

2. The semiconductor package of claim 1, wherein the contact-preventing member comprises:
a body portion formed on the upper edge surface of the semiconductor chip; and
a contact-preventing portion extending from the body portion and protruding from the upper edge surface of the semiconductor chip to prevent the contact between the conductive connecting member and the semiconductor chip.

3. The semiconductor package of claim 2, wherein the contact-preventing portion has a thickness less than that of the body portion.

4. The semiconductor package of claim 2, wherein the contact-preventing member further comprises a fillet portion on the upper edge surface of the semiconductor chip to connect the body portion with the contact-preventing portion.

5. The semiconductor package of claim 1, wherein the contact-preventing member is a part of the insulating layer pattern.

6. The semiconductor package of claim 5, wherein the contact-preventing member comprises a material substantially the same as that of the insulating layer pattern.

7. The semiconductor package of claim 6, wherein the contact-preventing member comprises oxide, polyimide or photosensitive polyimide.

8. The semiconductor package of claim 1, wherein the conductive connecting member comprises a conductive wire.

9. The semiconductor package of claim 1, further comprising a molding member formed on the upper surface of the package substrate to cover the semiconductor chip and the conductive connecting member.

10. The semiconductor package of claim 1, further comprising external terminals mounted on a lower surface of the package substrate.

11-14. (canceled)

15. A semiconductor package comprising:
a package substrate;
a semiconductor chip mounted on the package substrate, the semiconductor chip having a bonding pad;
a conductive connecting member electrically connected between the bonding pad and the package substrate; and
a contact-preventing member formed on an upper edge surface of the semiconductor chip between the bonding pad and a corner portion of the semiconductor chip to maintain a distance between the conductive connecting member and the semiconductor chip.

16. The semiconductor package of claim 15, further comprising: an insulating layer pattern formed on the semiconductor chip and formed with the contact-preventing member in a monolithic single body.

17. The semiconductor package of claim 16, wherein:
the insulating layer pattern and the contact-preventing member are disposed in a same direction; and
the contact-preventing member comprises a contact-preventing portion extended from a corner portion of the semiconductor as an overhanging portion to overhang the package substrate such that the conductive connecting member is prevented from contacting a side of the semiconductor chip.

18. The semiconductor package of claim 15, wherein:
the contact-preventing member comprises a body portion formed adjacent to the bonding pad on the upper edge surface of the semiconductor chip, and a contact-preventing portion extending from the body portion to protrude from the upper edge surface of the semiconductor chip to prevent the contact between the conductive connecting member and the semiconductor chip; and
the conductive connecting member contacts the contact-preventing portion of the contact-preventing member.

19. The semiconductor package of claim 16, wherein the insulating layer pattern has a constant thickness, and the contact-preventing member has a variable thickness.

20. The semiconductor package of claim 15, further comprising:
a second package substrate disposed on the insulating layer pattern;
a second semiconductor chip mounted on the second package substrate, the second semiconductor chip having a second bonding pad;
a second conductive connecting member electrically connected between the second bonding pad and the package substrate; and
a second contact-preventing member formed on an upper edge surface of the second semiconductor chip between the second bonding pad and a second corner portion of the second semiconductor chip to maintain a second distance between the second conductive connecting member and the second semiconductor chip.
